(19) United States
(12) Patent Application Publication
(10) Pub. No.: US 2026/0096358 A1
(43) Pub. Date: Apr. 2, 2026

(54) INTEGRATION OF OPTICALLY ACTIVE AND DIAMOND-BASED COLOR CENTERS WITH SEMICONDUCTOR SUBSTRATES FOR QUANTUM DEVICES

(71) Applicant: IONQ INC., College Park, MD (US)

(72) Inventors: Bartholomeus Johannes Machielse, Brighton, MA (US); Daniel Riedel, Somerville, MA (US); Zhuoxian Wang, Cambridge, MA (US); Chawina De-Eknamkul, Watertown, MA (US); Carsten Robens, Arlington, MA (US); Ankur Agrawal, Somerville, MA (US); Teodoro Graziosi, Abingdon (GB); Matthew Lee Markham, Wallingford (GB)

(73) Assignee: IONQ INC., College Park, MD (US)

(21) Appl. No.: 19/182,077

(22) Filed: Apr. 17, 2025

Related U.S. Application Data
(60) Provisional application No. 63/701,316, filed on Sep. 30, 2024.

(51) Int. Cl. H10N 99/00; H10H 20/01; H10H 20/812; H10H 20/826; H10N 97/00

(52) U.S. Cl. CPC H10N 99/05; H10H 20/0145; H10H 20/017; H10H 20/018; H10H 20/812; H10H 20/8264; H10N 97/00

(57) ABSTRACT

Methods for fabricating optically active quantum memories into quantum-grade diamond thin films and then bonding them to semiconductor substrates are described. Semiconductor substrates are optically and electronically functionalized in preparation for using a flip-chip bonding technique to bond the functionalized substrates to overgrown diamond thin films that host color centers. By purposefully growing quantum-grade diamond thin films and implanting them with color centers separately from fabrication processes that functionalize the substrates, the high quality, purity, and crystallinity of the thin films are preserved, while also allowing for further customization of the types of color centers that are implanted into the diamond.

### CROSS REFERENCE TO RELATED APPLICATION

This U.S. Non-Provisional Patent Application claims the benefit of and priority to U.S. Provisional Patent Application Ser. No. 63/701,316, entitled “Integrated Semiconductor and Photonic Element and Fabrication Thereof,” filed Sep. 30, 2024, and which is incorporated herein by reference in its entirety.

### TECHNICAL FIELD

The present disclosure relates to methods and systems for integrating diamond thin films and photonic integrated circuits for quantum information storage devices.

### BACKGROUND

Diamond is a sought-after host material for optically active quantum memories. However, growing quantum-grade diamond onto non-diamond substrates remains a challenge for both the scientific community and fabrication-based facilities. The precision and quality with which diamond is to be grown has not only limited its applicability for quantum devices, but has also limited the ability to produce diamond-based devices in standard foundry and cleanroom environments that largely rely on and cater to semiconductor-based fabrication techniques.

### BRIEF DESCRIPTION OF THE DRAWINGS

FIG. 1A illustrates a bulk wafer that includes integrated semiconductor and photonic elements, wherein the photonic elements have been fabricated into a diamond thin film and aligned with and bonded to semiconductor circuit elements within a semiconductor substrate of the bulk wafer, according to some embodiments.

FIG. 1B illustrates example layouts of the integrated semiconductor and photonic elements introduced in the bulk wafer that is shown in FIG. 1A, wherein the elements are configured for accessing, manipulating, and otherwise tuning optically active quantum memories that have been fabricated into the diamond thin film, according to some embodiments.

FIG. 2A illustrates a diamond substrate that is to be used as a base for growing diamond thin films onto a top surface of the diamond substrate, wherein the diamond substrate is cut and polished in preparation for the thin film growth, according to some embodiments.

FIG. 2B illustrates the resulting surface of the diamond substrate after polishing and etching, according to some embodiments.

FIG. 3A illustrates a diamond substrate that has been prepared to be used as a base for growing diamond thin films onto a top surface of the diamond substrate, according to some embodiments.

FIG. 3B illustrates ions being implanted at a given depth below a top surface of the diamond substrate in order to form a sub-surface smart-cut layer, according to some embodiments.

FIG. 3C illustrates a quantum-grade diamond thin film being grown on top of a damaged layer of the diamond substrate, according to some embodiments.

FIG. 4 illustrates diamond substrates laid out in a tiled pattern with engineered gaps left between the diamond substrates, wherein the engineered gaps are determined based on expected temperature gradients and electric field distributions in a diamond growth chamber that will be used to grow diamond thin films onto top surfaces of the diamond substrates, according to some embodiments.

FIG. 5 illustrates the overgrown diamond thin film being doped with ions in order to achieve an engineered specification for the diamond thin film layer, according to some embodiments.

FIG. 6 further illustrates alignment markers being etched or cut into the top surface of the overgrown diamond thin film, according to some embodiments.

FIG. 7A illustrates an overgrown diamond thin film that has been grown on top of a diamond substrate, wherein a nano-aperture is prepared via a masking step, according to some embodiments.

FIG. 7B illustrates a result of an ion implantation step, wherein ions have become embedded into both the resist and the overgrown diamond thin film, according to some embodiments.

FIG. 7C illustrates trenches that are etched into both the overgrown diamond thin film and damaged layers, in preparation for allowing access for etching fluid to reach the smart-cut layer, according to some embodiments.

FIG. 7D illustrates that the majority of the smart-cut layer has been selectively etched away, such that tethers between the damaged layer and diamond substrate remain, according to some embodiments.

FIG. 7E illustrates an application of a bonding layer to the top surface of the overgrown diamond thin film, and also to a top surface of a separate semiconductor substrate, according to some embodiments.

FIG. 7F illustrates a flip-chip bonding technique, wherein the overgrown diamond thin film is bonded to the semiconductor substrate via the bonding layer, according to some embodiments.

FIG. 7G illustrates a removal of the damaged layer and further etching of the overgrown diamond thin film layer, wherein an amount that is etched away from the overgrown diamond thin film layer corresponds to intended optical properties of the resulting optically active quantum memories following the etching process, according to some embodiments.

FIGS. 8A and 8B illustrate cross-sectional and top-down view, respectively, of a quantum information storage device that is fabricated using a quantum-grade diamond thin film that has been bonded to a semiconductor substrate, according to some embodiments.

FIG. 9 further illustrates example layouts of the integrated semiconductor and photonic elements introduced in the bulk wafer that is shown in FIGS. 1A and 1B, wherein the fabrication processes described herein enable those layouts, according to some embodiments.

FIG. 10 is a block diagram that illustrates an example computing device that may be used in at least some embodiments.

While embodiments are described herein by way of example for several embodiments and illustrative drawings, those skilled in the art will recognize that embodiments are not limited to the embodiments or drawings described. It should be understood, that the drawings and detailed description thereto are not intended to limit embodiments to the particular form disclosed, but on the contrary, the intention is to cover all modifications, equivalents and alternatives falling within the spirit and scope as defined by the appended claims. It is to be understood that the disclosed embodiments are merely examples and other embodiments can take various and alternative forms. The drawings are not necessarily to scale; some features could be exaggerated or minimized to show details of particular components. Therefore, specific structural and functional details disclosed herein are not to be interpreted as limiting, but merely as a representative bases for teaching one skilled in the art to variously employ the embodiments.

As used throughout this application, the word “may” is used in a permissive sense (i.e., meaning having the potential to), rather than the mandatory sense (i.e., meaning must). Similarly, the words “include,” “including,” and “includes” mean including, but not limited to. When used in the claims, the term “or” is used as an inclusive or and not as an exclusive or. For example, the phrase “at least one of x, y, or z” means any one of x, y, and z, as well as any combination thereof. Furthermore, words such as “first,” “second,” “third,” etc. are meant to be used to distinguish a “first” element with respect to a “second” element, and so on, and should not be interpreted as limiting, but merely as a chosen naming convention for ease of discussion herein.

### DETAILED DESCRIPTION

The present disclosure relates to methods and systems for fabricating integrated semiconductor and photonic elements in order to construct quantum information storage devices. In some embodiments, an integrated semiconductor and photonic element comprises a semiconductor substrate with one or more diamond thin films bonded onto a surface of the semiconductor substrate. The one or more diamond thin films may implement a photonic element. For example, alignment markers etched into the diamond thin films may be used to align the diamond thin films with circuits patterned into the semiconductor substrate at precise (e.g. controlled) locations in order to align interfaces of a photonic element of the diamond thin film with corresponding interfaces of a circuit patterned into the semiconductor substrate. As an example, a pre-patterned circuit element may be patterned into the semiconductor substrate and may include an interface that is intended to interact with a photonic element, such as a photonic device comprising a color center that is integrated as part of an implementation of a quantum memory, quantum repeater, a quantum emitter, a quantum waveguide, or a quantum resonator.

In some embodiments, a plurality of integrated photonic and semiconductor elements is formed (e.g., via a combination of fabrication process steps and a bonding technique) on a bulk wafer and are configured in a way that enable the bulk wafer to be ingested by a foundry cleanroom without further modification. For example, the bulk wafer with the plurality of integrated photonic and semiconductor elements may be transported to the foundry cleanroom and used directly as input wafers for manufacturing other devices that further build upon the integrated photonic and semiconductor elements on the bulk wafer. In this way, large scale manufacture of quantum devices that include integrated photonic and semiconductor chips is enabled.

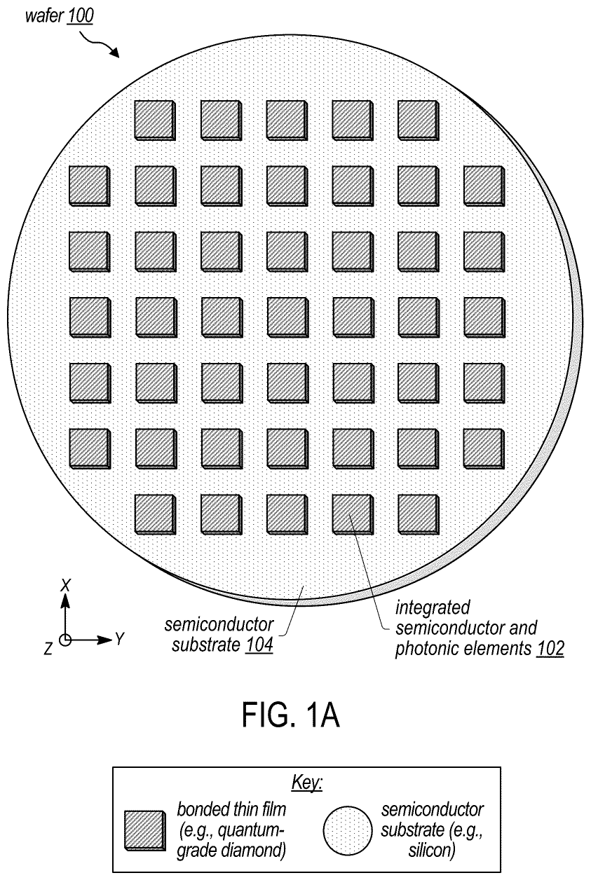

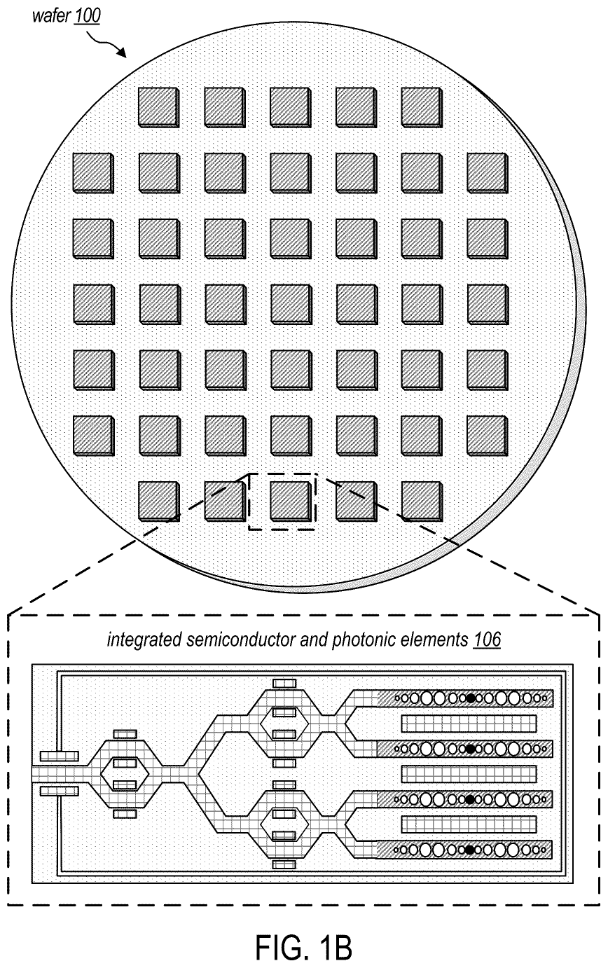

In some embodiments, the wafers are between approximately 25 and 450 mm in diameter and include many integrated photonic and semiconductor elements on the wafer. This is further illustrated in FIG. 1A, wherein there are 45 distinct integrated semiconductor and photonic elements on a given bulk wafer, for example. The bulk wafer with integrated semiconductor and photonic elements, such as that which is shown in FIG. 1A, can then be directly implemented into a subsequent fabrication process within a foundry cleanroom. This implementation into the foundry cleanroom is further simplified due to the placements of the diamond thin films and their corresponding alignment markers that are visible on the semiconductor substrate material, which can be identified by various fabrication tools and equipment that are part of the larger foundry cleanroom manufacturing process.

Moreover, the properties of the diamond thin films are selected such that standard semiconductor fabrication equipment can be used to form the bulk wafers with integrated semiconductor and photonic elements. For example, micro-and/or nano-semiconductor fabrication equipment may be used.

In some embodiments, some combination of the electrical, optical, mechanical, chemical, and topological properties of the diamond thin films used in the integrated photonic and semiconductor elements are selected such that semiconductor fabrication equipment can be used to manufacture the integrated photonic and semiconductor devices, such as the bulk wafer with integrated photonic and semiconductor elements. For example, a carbon isotope concentration of the diamond thin films may be precisely selected and subsequently controlled, during fabrication, to achieve one or more of those properties. In another example, a single carbon isotope, such as carbon-12, may be particularly selected for use in growing the diamond thin films, such that spin properties of the embedded color centers (see, for example, color center 720 and SiV color center 802) are enhanced within the inert local environment that is ensured by the use of carbon-12.

As used herein, alignment markers on the diamond thin films of the respective integrated photonic and semiconductor elements may provide one or more uses both during manufacturing of the bulk wafer with integrated semiconductor and photonic elements and during subsequent fabrication within the foundry cleanroom. In a first example, the alignment markers on the diamond thin films enable the localization and identification of color centers in the diamond thin films. In a second example, alignment markers may be formed on the semiconductor substrates for use in aligning the diamond thin films with respect to components that have been fabricated onto or into the semiconductor substrates.

In some embodiments, a diamond thin film may be doped with ions in order to engineer certain electrical, optical, or chemical properties. As another example, a diamond thin film may be implanted with ions in a concentrated manner, and at specified and intentional locations, in order to form a color center at respective ones of the specified and intentional locations. Such color centers may be used in quantum emitters, quantum memories, quantum repeaters, quantum waveguides, quantum resonators, etc.

In some embodiments, the underlying semiconductor substrate is pre-patterned with circuit elements, over which the diamond thin films are bonded. Also, in some embodiments, the diamond thin films may be bonded to blank (e.g. un-patterned) portions of the semiconductor substrate. In some embodiments, a protective layer, such as a cladding layer, may be formed over the integrated photonic and semiconductor elements. For example, a cladding layer of an integrated photonic and semiconductor element may cover the diamond thin film and also portions of the semiconductor substrate of a given integrated photonic and semiconductor element, for example that extend out beyond the diamond thin film.

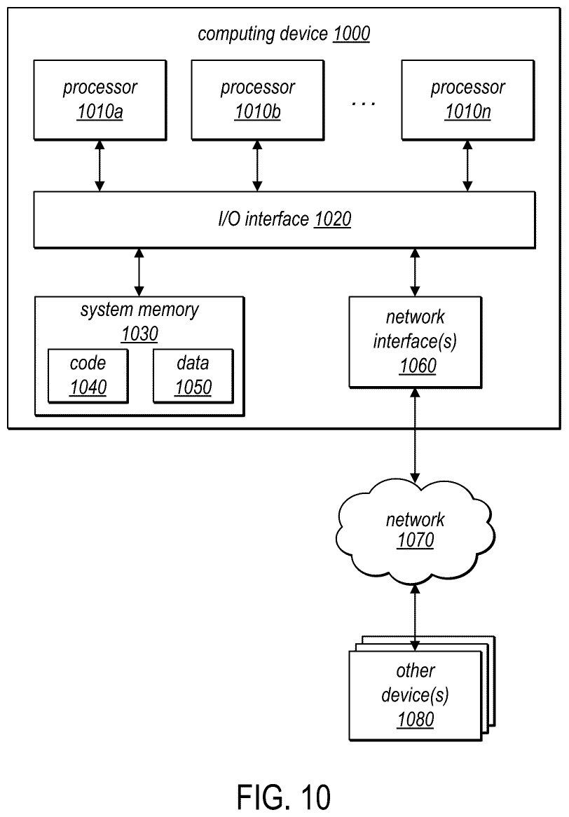

The present disclosure continues with examples of bulk wafers that include integrated semiconductor and photonic elements. After providing explanations of the fabrication processes and techniques used to arrive at such integrated semiconductor and photonic elements, an example of applying the methods and bulk wafers described herein for generating quantum memory modules, quantum sensing modules, or other related forms of quantum devices is detailed. Finally, a description of an example computing system which may be used to fabricate the various components, modules, systems, and/or devices is provided in FIG. 10. Various examples are provided throughout the specification. A person having ordinary skill in the art should understand that the previous and following description of constructing and subsequently utilizing integrated semiconductor and photonic elements within a bulk wafer is not to be construed as limiting as to the implementation of said processes, devices, or portions thereof.

Throughout the following description herein, X, Y, and Z axes are denoted throughout the figures. The use of X, Y, and Z axes is meant for ease of discussion herein in order to reference a given face or surface of a three-dimensional (3D) structure with respect to another face or surface of the 3D structure, and should not be misconstrued as specific to the sole orientation. Similarly, language such as “length,” “width,” and “thickness” may also be used for ease of discussion herein in order to reference one dimension with respect to another, and to convey approximate measurements of the various components of such 3D structures.

FIG. 1A illustrates a top view (e.g., the XY plane) of a bulk wafer that includes integrated semiconductor and photonic elements, wherein the photonic elements have been fabricated into a diamond thin film and aligned with and bonded to semiconductor circuit elements within a semiconductor substrate of the bulk wafer. FIG. 1B then depicts example layouts of the integrated semiconductor and photonic elements introduced in the bulk wafer that is shown in FIG. 1A, wherein the elements are configured for accessing, manipulating, and otherwise tuning optically active quantum memories that have been fabricated into the diamond thin film, according to some embodiments.

As shown in FIG. 1A, multiple integrated semiconductor and photonic elements are formed on a bulk wafer. The semiconductor and photonic elements are “integrated” based, at least in part, on alignment markers that are used to align (1) photonic elements that have been fabricated into an overgrown diamond thin film with (2) semiconductor elements that have been patterned onto semiconductor substrate 104. Integrated semiconductor and photonic elements 102, as used herein, therefore refers to components of a bulk wafer that are aligned, coupled, or otherwise physically connected via bonding techniques such that those components are configured for operation of quantum devices. For example, bulk wafer 100 may include optically active quantum memory modules, wherein respective ones of the optically active quantum memory modules include at least one silicon-vacancy color center (e.g., the photonic element) that is manipulated in some way by a semiconductor element that the photonic element is coupled to.

Bulk wafer 100 additionally includes portions of semiconductor substrate 104 that are not bonded to overgrown diamond thin films, such that semiconductor substrate 104 remains exposed to the surface along those portions of the XY plane.

Moreover, and as used herein, “formed” may refer to elements that are fabricated into a semiconductor substrate, elements that are fabricated into an overgrown diamond thin film, elements such as integrated photonic and semiconductor elements that have been bonded to one another, or any combination thereof.

Integrated semiconductor and photonic elements 102 refer to a plurality of integrated semiconductor and photonic elements that are formed onto bulk wafer 100. The 45 integrated semiconductor and photonic elements shown specifically in bulk wafer 100 are meant to illustrate the repeatability, scalability, and customizability that is enabled by the processes described herein. In other embodiments, more or less integrated semiconductor and photonic elements may be formed onto some other bulk wafer, and the integrated elements may also vary in position, shape, and size, according to a given implementation of the particular bulk wafer for its corresponding quantum application.

Moreover, spacing between the 45 integrated semiconductor and photonic elements may also vary. For example, a spacing of between 5 μm and 20 mm in the X and Y dimensions, respectively, may be selected as part of an overall layout of wafer 100 in order to leave sufficient space when later dicing wafer 100 into 45 separate chips, and so as not to risk damaging the chips or their components.

A number of total integrated semiconductor and photonic elements that are formed onto a given bulk wafer may also depend upon a diameter (e.g., in the XY plane) of the wafer. As used herein, a bulk wafer may refer to a wafer with a diameter of between 25 and 450 millimeters (mm).

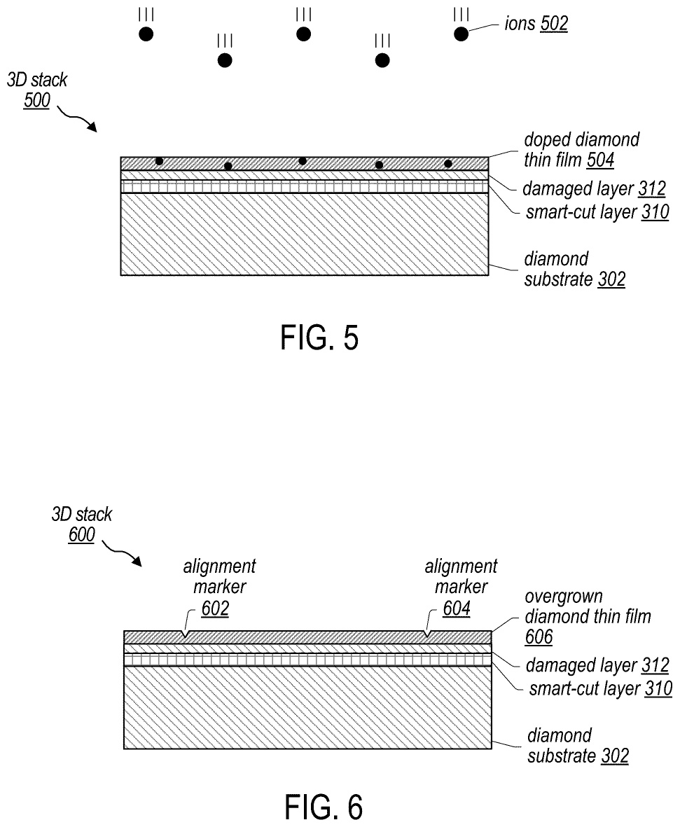

Integrated semiconductor and photonic element 106 is a 3D stack that includes some number of semiconductor circuit elements that are fabricated into or onto semiconductor substrate 104, and some other number of photonic elements that have been patterned into overgrown diamond thin films that are subsequently bonded to semiconductor substrate 104. As additionally illustrated throughout FIG. 5-7G, alignment markers that are etched into top surfaces of the overgrown diamond thin films and into top surfaces of semiconductor substrate 104 are used to align those various semiconductor and photonic elements 102 with respect to one another during a flip-chip bonding process step.

Dashed lines that depict that a given one of integrated semiconductor and photonic elements 102 and some surrounding exposed portions of semiconductor substrate 104 may include the elements within integrated semiconductor and photonic element 106 illustrates that the methods described herein can be used for large-scale production of quantum information storage devices, wherein hundreds or thousands of optically active quantum memories may be fabricated in parallel and within a given wafer 100.

As illustrated with integrated semiconductor and photonic elements 106, color centers are created into the overgrown diamond thin films such that silicon-vacancy (SiV⁻) or other color centers can be utilized. The respective SiV⁻ color center may then be implemented as quantum memory modules, wherein an optically accessible memory qubit is mapped to an electron of a given SiV⁻ color center, and an optically inaccessible memory qubit is mapped to a silicon nucleus of the given SiV⁻ color center. A series of thru-holes in the overgrown diamond thin films on either side of SiV⁻ color center are also fabricated using the methods described herein, wherein the thru-holes collectively function as mirrors that temporarily trap incoming light, thus enabling quantum information to be exchanged and stored using optically accessible memory qubits of the SiV⁻ color centers. Additional examples and description pertaining to the fabrication of SiV⁻ color centers and thru-holes are provided with regard to color center 720, quantum information storage device 800, and portion 900 of wafer 100 herein.

The material used for semiconductor substrate 104 may be silicon, silicon nitride, silicon oxide, lithium niobate, any III-V semiconductor (e.g., a semiconducting compound with an element of group III of the periodic table of elements and an element of group V of the periodic table of elements, such as gallium arsenide), aluminum nitride, aluminum oxide, or any other semiconducting material that is compatible with foundry and cleanroom processing techniques. In some embodiments, semiconductor substrate 104 may be monolithic. In other embodiments, semiconductor substrate 104 instead includes two or more layers of different semiconducting materials.

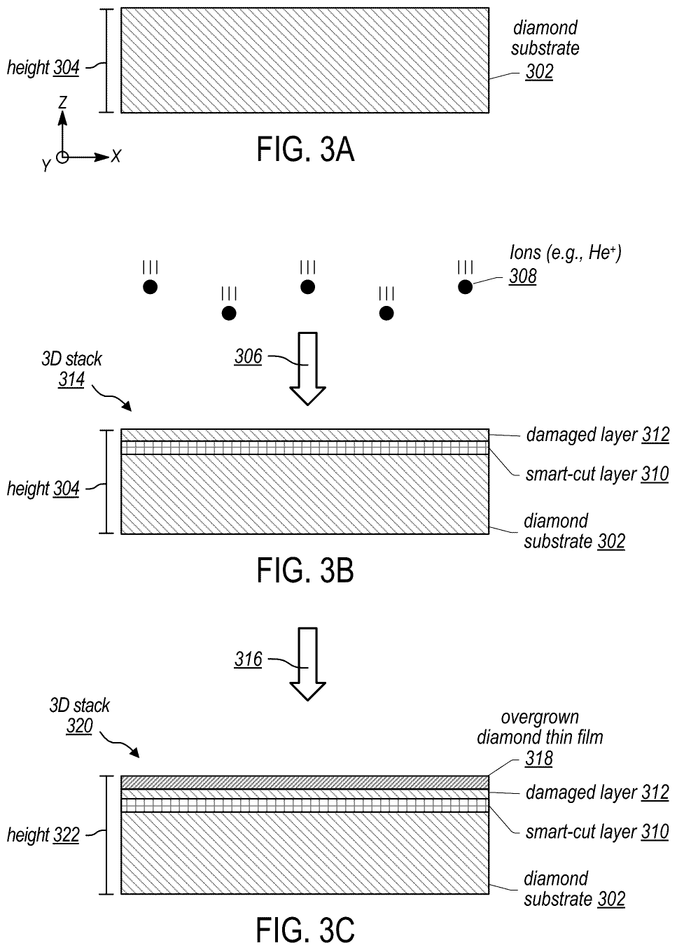

As indicated by the Key in FIG. 1A, the bonded thin film is made from high purity, single crystal diamond, such as quantum-grade diamond, and has a thickness of approximately 300 nanometers (nm) in the Z dimension. The quality and growth process for the overgrown diamond thin film is additionally described below, with regard to overgrown diamond thin film 318 in FIG. 3C. In some embodiments, the overgrown diamond thin film may also be doped in order for the thin film to exhibit certain thermal or electrical properties, and in preparation for later quantum devices or components that are fabricated into the doped diamond thin film layer. An example of a doped, overgrown diamond thin film is additionally described below, with regard to doped diamond thin film 504 in FIG. 5.

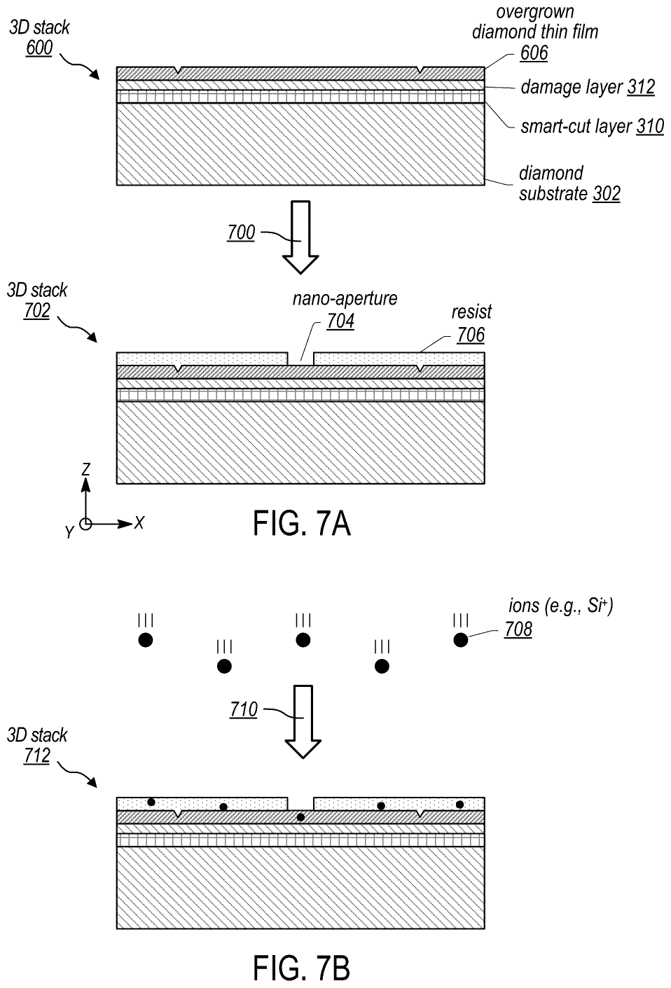

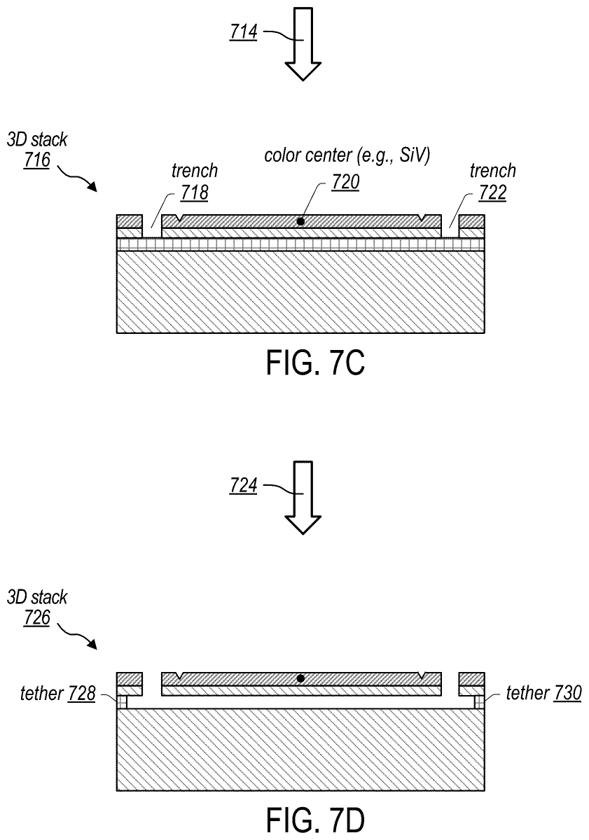

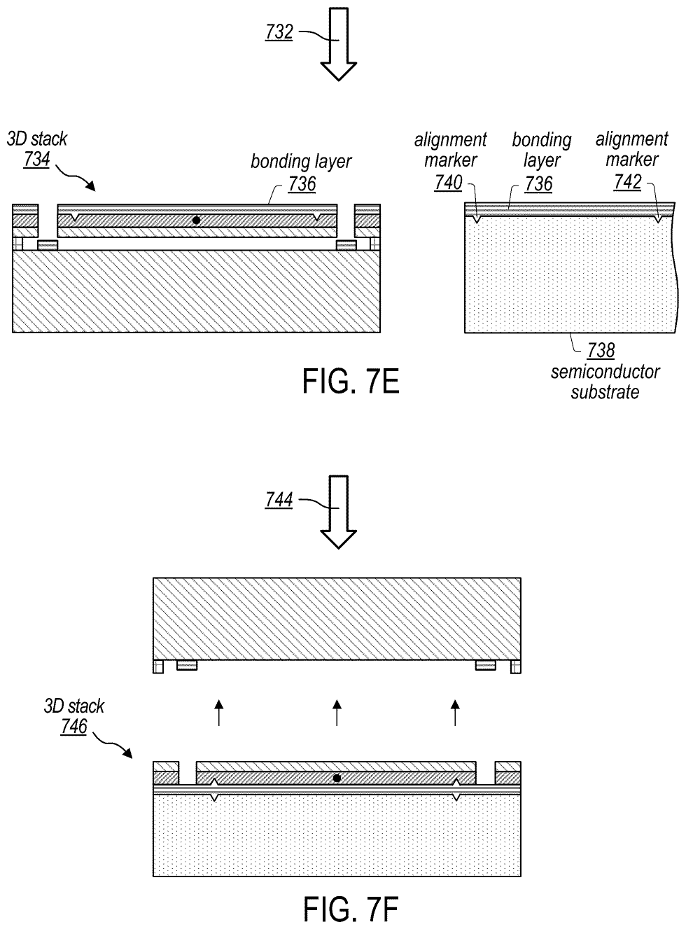

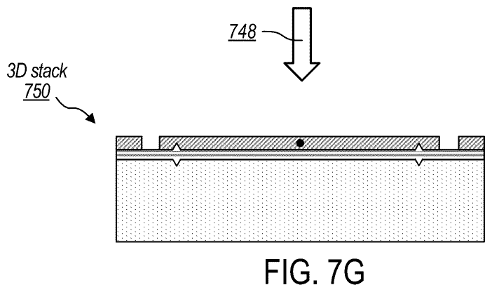

As introduced above, the overgrown diamond thin film is bonded to semiconductor substrate 104 using an adhesion or bonding layer. The bonding layer is made from one or more metal, oxide, semiconductor, or organic adhesives that are compatible with foundry and cleanroom processing techniques. In a given example, gold (Au) may be selected to be used as the bonding layer for its electrical and thermal properties that cause it to be compatible with the implementation of quantum devices. The deposition of the bonding layer and its usage during a flip-chip bonding technique are additionally described with regard to bonding layer 736 and FIGS. 7E and 7F below.

Moreover, if or when bulk wafer 100 undergoes further processing through a cleanroom, a cladding layer may be deposited onto the top surfaces of the integrated semiconductor and photonic elements of bulk wafer 100 in order to protect them during subsequent fabrication processing steps. The cladding layer may include an oxide, nitride, or organic material, and may then be removed once fabrication processing steps that are possibly damaging to the integrated semiconductor and photonic elements are complete.

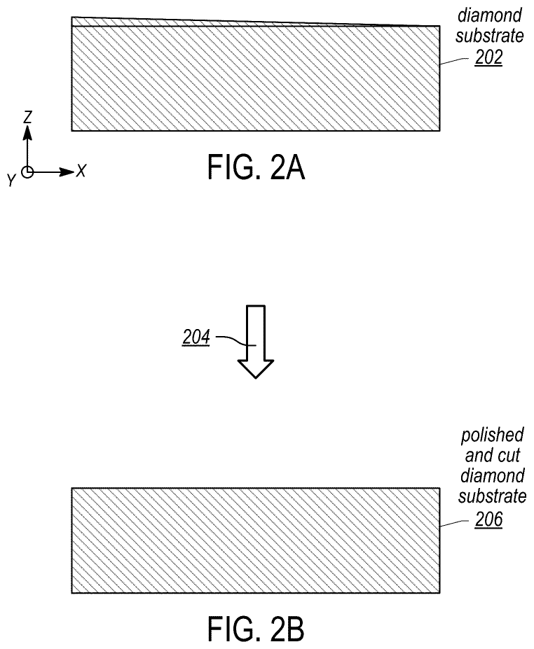

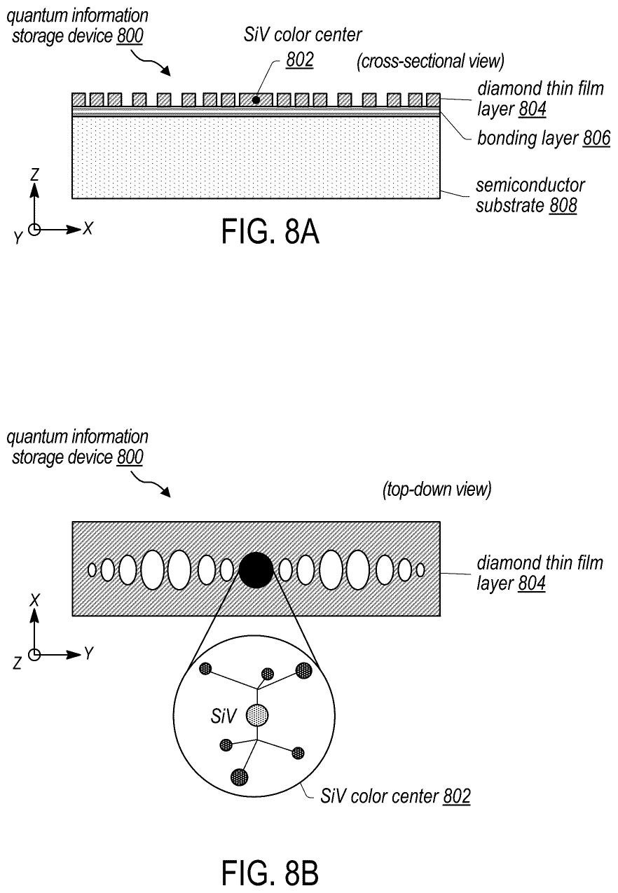

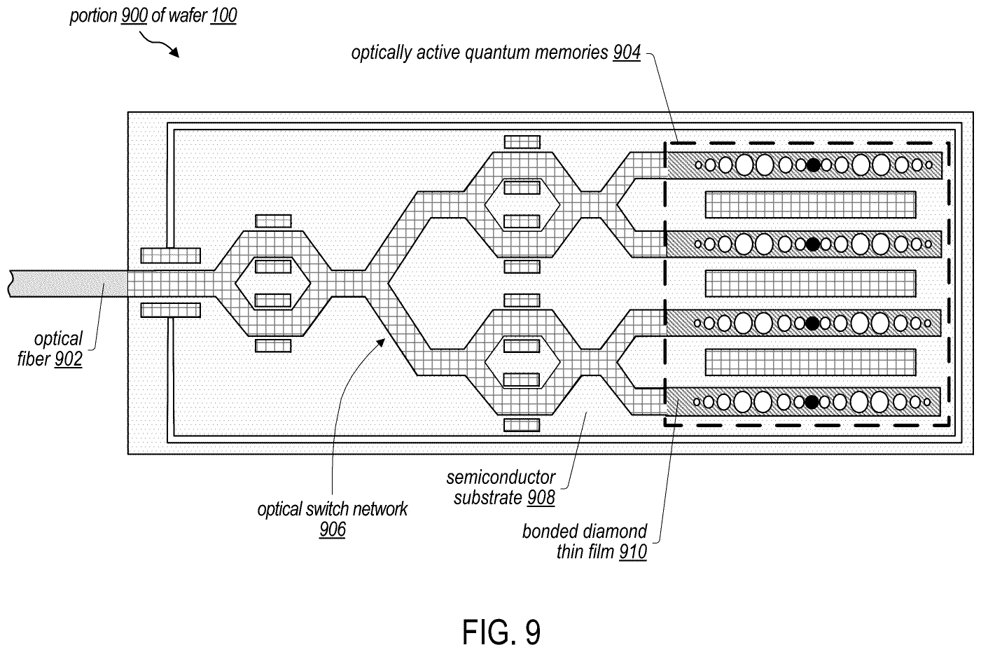

The following FIG. 2A-7G and the corresponding description herein pertains to fabrication and bonding techniques that are used to construct a bulk wafer with integrated semiconductor and photonic elements, such as that which is illustrated via bulk wafer 100 in FIGS. 1A and 1B. Specifically, FIG. 2A-6 pertain to methods for preparing the overgrown diamond thin film, prior to the flip-chip bonding process that is then detailed in FIG. 7A-7G. FIG. 8A-9 then illustrate various extensions to the fabrication and bonding techniques of FIG. 2A-7G for a given implementation of bulk wafer 100, wherein thru-holes are additionally fabricated, such that color center 720 may be implemented as part of a quantum memory module.

FIG. 2A illustrates a diamond substrate that is to be used as a base for growing diamond thin films onto a top surface of the diamond substrate (additionally described below with regard to FIG. 3A-3C), wherein the diamond substrate is cut and polished in preparation for the thin film growth. FIG. 2B then illustrates the resulting surface of the diamond substrate, according to some embodiments.

FIG. 2A illustrates the diamond substrate that is to be used to grow diamond thin films, wherein the diamond substrate is cut and polished to prepare it for use in growing diamond thin films, according to some embodiments. As used herein, the diamond substrate that is shown in FIG. 2A may also be referred to as a bulk diamond, a carrier diamond, or some other diamond starting or seed material.

Initially, and at a moment in time depicted in FIG. 2A, a top surface (e.g., in the XY plane) of diamond substrate 202 may have a given roughness that is outside of bounded parameters that ensures uniform growth of another diamond thin film layer onto the top surface of diamond substrate 202. As also shown in FIG. 2A, diamond substrate 202 may resemble a moment in time prior to having cut the top surface along a given plane. As such, the top surface might not yet be completely uniform in the Z dimension. For ease of visualization in the figure, this non-uniformity and roughness that an initial diamond substrate 202 may have is illustrated by an angled top surface.

Arrow 204 thus resembles one or more pre-preparation steps in which diamond substrate 202 is cut along a given plane, polished, and smoothed, in preparation for thin film growth.

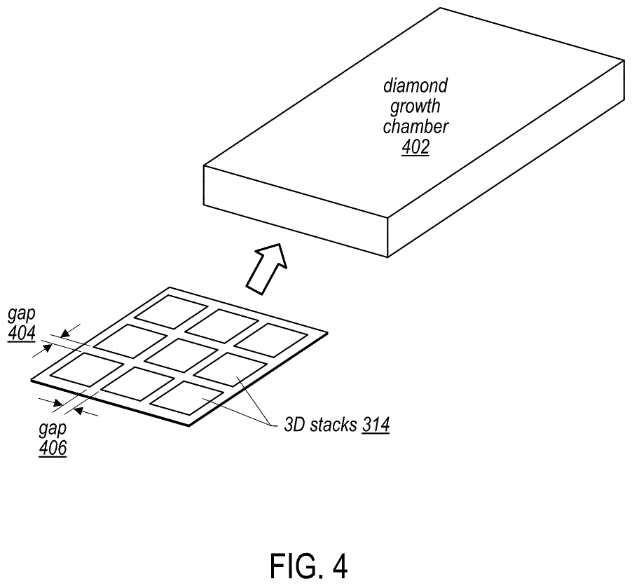

In some embodiments, diamond substrate 202 may be cut with a miscut of between 0.5° and 1.7° off of the (001) plane, or may be cut with a miscut of between 0.8° and 2° off of the (001) plane, depending on a process pressure temperature and on a methane fraction that is to be used to grow the later overgrown diamond thin film layer (see also FIG. 4). For example, a higher pressure, temperature, and methane fraction growth process requires a higher miscut to sustain the correct morphology. However, there may be an upper limit on the miscut, wherein, above that upper limit, the morphology becomes dominated by macro-steps. Moreover, a miscut angle may be further tuned, intentionally engineered, or otherwise selected according to a particular diamond thin film growth recipe for a given implementation of diamond growth chamber 402, and according to intended optical properties of the resulting optically active quantum memories.

The diamond substrate 202 is also prepared with a low damage method since subsurface damage, other than a purposefully created damage layer, may impart a change of morphology of the later overgrown diamond thin film layer. In some embodiments, inductively coupled plasma (ICP) etching, chemical mechanical polishing (CMP), ion beam etching or milling (IBE), or some combination thereof may be used to smooth the top surface without imparting so much damage to the top surface as to make the diamond substrate 202 unusable afterwards. In other embodiments, a 0-1 μm grit or other μm-sized diamond powder may be used during a scaife-based polishing process to polish the surface of diamond substrate 202.

FIG. 2B illustrates the resulting surface of the diamond substrate, denoted as diamond substrate 206 in the figure, after polishing and etching, which ensures flatness of the surface, according to some embodiments.

FIGS. 3A, 3B, and 3C next depict a process of growing a diamond thin film layer onto a top surface of the diamond substrate 206, wherein the growth process is then further discussed with regard to FIG. 4. As additionally described in the following paragraphs, ion implantation is firstly used to generate a smart-cut layer. The smart-cut layer is later used (see FIG. 7C-7F) as a sacrificial layer that enables the overgrown diamond thin film layer to be easily separated (e.g., via a lift-off or other electrochemistry-based process) from the underlying diamond substrate, in preparation for the flip-chip bonding technique between the semiconductor substrate and overgrown diamond thin film.

FIG. 3A illustrates a diamond substrate that has been prepared to be used as a base for growing diamond thin films onto a top surface of the diamond substrate, according to some embodiments.

At a moment in time depicted in FIG. 3A, diamond substrate 302 has already been prepared and treated using the processes described above with regards to arrow 204. As shown in FIG. 3A, diamond substrate has some height 304 in the Z dimension. Height 304 represents the thickness of diamond substrate 302 prior to growing the overgrown diamond thin film 318 onto the top surface of diamond substrate 302.

FIG. 3B illustrates ions being implanted at a given depth below a top surface of the diamond substrate in order to form a sub-surface smart-cut layer, according to some embodiments.

Arrow 306 thus indicates an ion implantation step in which ions 308 are implanted at a given depth below the top surface of diamond substrate 302.

As an example, 2 Mega electron Volt (MeV) carbon ions (C⁺) at a dose of 2×10¹⁶/cm² and at room temperature may be used during ion implantation step 306. This may result in a high-damage layer that is approximately 900 nm deep (e.g., below the top surface of diamond substrate 302) and 400 nm thick in the Z dimension denoted in FIG. 3B. Note that these conditions are given as an example and it should be understood that other ions, such as helium ions (He⁺), and other conditions may be used. Then, 3D stack 314 may then be subjected to an annealing step at 1200° C. as well. In such embodiments, this is also encompassed by arrow 306. The annealing temperature and duration may vary, but the annealing parameters are selected such that the high-damage layer is converted into graphite, thus resulting in smart-cut layer 310.

While the objective of ion implantation step 306 is to form smart-cut layer 310, a slightly damaged layer 312 of the overall diamond substrate 302 is also formed.

As shown in FIG. 3B, the ion implantation and annealing steps are used to form smart-cut layer 310, such that, moving along the Z dimension of resulting 3D stack 314, a portion of the diamond substrate is below the smart-cut layer 310 (e.g., diamond substrate 302) and another portion of diamond substrate remains above the sub-surface smart-cut layer 310 (e.g., damaged layer 312). As also illustrated in FIG. 3B, the ion implantation step denoted by arrow 306 does not change the height 304 of the 3D stack 314 with respect to that which is shown in FIG. 3A.

FIG. 3C illustrates a quantum-grade diamond thin film being grown on top of a damaged layer of the diamond substrate, according to some embodiments.

Arrow 316 depicts a growth process that is additionally described below with regard to FIG. 4. A result of that growth process is 3D stack 320, wherein an overgrown diamond thin film 318 has been grown over top of damaged layer 312. Moving along the Z dimension of resulting 3D stack 320, a portion of the diamond substrate is below the smart-cut layer 310 (e.g., diamond substrate 302), which is then followed by the smart-cut layer 310, the damaged layer 312, and the overgrown diamond thin film 318.

As also illustrated in FIG. 3C, the diamond thin film growth process 316 changes the height of 3D stack 320 with respect to 3D stack 314, such that a difference between height 322 and height 304 is the thickness of overgrown diamond thin film 318.

FIG. 4 illustrates diamond substrates laid out in a tiled pattern with engineered gaps left between the diamond substrates, wherein the engineered gaps are determined based on expected temperature gradients and electric field distributions in a diamond growth chamber that will be used to grow diamond thin films onto top surfaces of the diamond substrates, according to some embodiments.

FIG. 4 depicts a plurality of 3D stacks 314 that are laid onto a Chemical Vapor Deposition (CVD) stone and then input into a diamond growth chamber 402. The diamond growth chamber 402 may resemble a CVD chamber, according to some embodiments.

In some embodiments, 3D stacks 314 are arranged in a tiled or grid pattern as shown in FIG. 4. Gaps 404 and 406 are left between the respective 3D stacks 314, wherein the gap distance is selected based on the temperature gradient of diamond growth chamber 402 and the electrical field distribution to be used in diamond growth chamber 402. For example, for a 2.4 GHz diamond growth chamber 402, a desired gap spacing is ˜0.5 mm. In some embodiments, gaps 404 are equal to gaps 406. However, in other embodiments, gaps 404 can be tuned individually from gaps 406 for optimal diamond thin film growth parameters within diamond growth chamber 402.

The 3D stacks 314 are processed through diamond growth chamber 402 for a given amount of time at a given temperature gradient, wherein, for at least a portion of that amount of time, an electrical field is emitted in a presence of a gas or vapor, such as methane, nitrogen, silicon, germanium, etc. The temperature gradient, electrical field, and other conditions that are applied during processing through diamond growth chamber 402 are selected to ensure thickness uniformity of the resulting overgrown diamond thin films.

Moreover, by processing multiple 3D stacks 314 through diamond growth chamber 402 at the same time, uniformity of the diamond thin films that result in the bonded thin films of integrated semiconductor and photonic elements 102 is ensured across wafer 100. More specifically, the diamond thin film growth process described in FIG. 3A-4 ensures uniformity of the overgrown diamond thin film layer themselves, and across multiple diamond thin film layers with respect to one another, thus ensuring uniformity and repeatability across wafer 100.

In some embodiments, the diamond thin films that are grown onto top surfaces of 3D stacks 314 have a largest linear dimension of at least 200 μm, a thickness of at least 0.1 μm, and a thickness variation of no more than 10% over the largest linear dimension. Note that the thickness variation is calculated as (maximumthickness−minimumthickness)÷averagethickness. So, a thickness variation of no more than 10% corresponds to an average thickness variation of +/−5%.

In some embodiments, the diamond thin films grown on the 3D stacks 314 have a background luminescence, as measured by photoluminescence, of less than 400k photons total at all wavelengths between than 530 nm and 900 nm, 40k photons when passed through a 13 nm wide filter centered at 737.0 nm, or 200 photons when passed through a 200 GHz filter centered at 737.0 nm, and when illuminated by 6 mW of 520 nm laser light. Such background luminescence properties may be specifically engineered according to a given implementation of wafer 100 for particular types of quantum devices, such as for quantum information storage devices.

In some embodiments, diamond thin films grown onto the 3D stacks 314 enable later color centers that are implanted into those diamond thin films to have a Hahn-Echo decoherence time equal to or greater than 0.01 ms, 0.05 ms, 0.1 ms, 0.3 ms, 0.6 ms, 1 ms, 5 ms, or 15 ms after implanting with nitrogen 15 ions at 50 keV energy with a dose of 5×10¹⁰ ions/cm² (see also FIG. 5 and ions 502). Such Hahn-Echo decoherence time properties may be specifically engineered according to a given implementation of wafer 100 for particular types of quantum devices, such as for quantum information storage devices. Specifically, Hahn-Echo decoherence time of resulting optically accessible and inaccessible memory qubits may be tuned according to the temperature and electrical field conditions that are fixed during the growth process of the overgrown diamond thin film layers.

In some embodiments, the thickness of the overgrown diamond thin films may be approximately 0.2 μm, approximately 0.5 μm, approximately 1 μm, approximately 5 μm, or approximately 10 μm, depending on specific design specifications intended for the resulting optically active quantum memories of wafer 100.

Various parameters of the fabrication tools used for ion implantation and annealing steps 306 and growth process 316 may be tuned, modified, or otherwise optimized such that the following conditions of 3D stack 320 are met. First, the top surface of overgrown diamond thin film 318 has a Root Mean Square (RMS) roughness of less than 1 nm. Second, overgrown diamond thin film 318 has a high thickness uniformity of less than 10 nm of thickness variation per mm. Third, that there is low material adsorption. Fourth, the surface area (e.g., in the XY plane) of overgrown diamond thin film 318 is at least 100 μm×100 μm. Fifth, there is low defect density in 3D stack 320.

Moreover, overgrown diamond thin film 318 is also fabricated, via methods described with regards to FIG. 2A-4, such that overgrown diamond thin film 318 can host high quality color centers that can be implemented as part of quantum memory modules. As introduced above, the processes described herein enable overgrown diamond thin film 318 to be classified as quantum-grade diamond. Specifically, overgrown diamond thin film 318 can host color centers with an NV⁻ coherence time of greater than 10 μs, and with SiV⁻optical linewidths of less than 500 MHz, less than 400 MHz, less than 300 MHz, less than 250 MHz, less than 200 MHz, and 100 MHz. Such parameters may be specifically engineered or otherwise tuned during the growth process according to intended optical parameters of the corresponding color centers and/or supporting and surrounding optical structures, such as the thru-holes shown in FIGS. 8A and 8B herein.

FIG. 5 illustrates the overgrown diamond thin film being doped with ions in order to achieve an engineered specification for the diamond thin film layer, according to some embodiments.

In some embodiments, ions 502 may be implanted to the diamond thin film layer to yield doped diamond thin film 504. In some embodiments, the ions may be selected and applied to modify optical properties, electrical properties, thermal properties, chemical properties, or some combination of properties therein of the diamond thin film. The ion type and concentration may be selected to achieve engineered specifications for the diamond thin film. In some embodiments, ions 502 may resemble nitrogen ions, which are implanted into 3D stack 500 at 50 keV energy with a dose rate of 5×10¹⁰ ions/cm².

In other embodiments, ions 502 may resemble nitrogen ions, and are implanted to yield a nitrogen-doped diamond thin film 504. In such embodiments, the diamond thin film layer is thus pre-prepared for the later ion implantation step that illustrated in FIG. 7B, wherein, due to the nitrogen-doped diamond thin film layer, the charge state of the resulting color center is ensured to be SiV⁻. As such, ions 502 that are used to generate doped diamond thin film 504 are purposefully selected as a method for tuning or otherwise controlling a charge state (e.g., an electrical property) of the resulting color center 720 (see also FIG. 7C). As an additional example, a nitrogen-doped diamond thin film 504 may provide a layout for additional background nitrogen-vacancy color centers that may be formed into the overgrown diamond thin film layer.

Moreover, if a nitrogen gas is emitted during a chemical vapor deposition processing step (see also arrow 316 in FIG. 3C) of growing overgrown diamond thin film layer 318, then additional ions 502 may not be implanted into the overgrown diamond thin film layer, since a doping concentration has already been achieved. Alternatively, if no additional gas is emitted during a chemical vapor deposition processing step described by arrow 316 in FIG. 3C, then additional ions 502 may indeed be implanted into the overgrown diamond thin film layer in order to achieve similar doping-based properties of the overgrown diamond thin film layer, and prior to proceeding to the etching of alignment markers 602 and 604, which are illustrated in the following FIG. 6.

FIG. 6 further illustrates alignment markers being etched or cut into the top surface of the overgrown diamond thin film, according to some embodiments.

In some embodiments, the overgrown diamond thin film 318 is further etched with alignment markers 602 and 604, resulting in overgrown diamond thin film 606. Alignment markers 602 and 604 may be etched into overgrown diamond thin film 318 in order to serve multiple purposes. For example, and as later shown in FIGS. 7A and 7B herein, alignment markers 602 and 604 may be used as reference points in order to align 3D stack 702 in preparation for implanting ions 708 that then are implemented as color centers. The alignment markers thus denote the exact placements of the color centers that are to be fabricated into the overgrown diamond thin films, and enable a 100 nm accuracy of those placements.

In some embodiments, alignment markers 602 and 604 are separated by approximately several hundreds of microns in the X dimension of 3D stack 600.

Alignment markers 602 and 604 are meant to be illustrative in nature, and it should be understood that more or less alignment markers than the two shown in FIG. 6 are also meant to be incorporated into the discussion herein. For example, alignment markers are etched into respective ones of the overgrown diamond thin film layers that are later bonded to semiconductor substrate 104, such that the plurality of integrated semiconductor and photonic elements 102 are formed onto wafer 100. As such, tens, hundreds, or even thousands of alignment markers may be used in order to construct the entirety of wafer 100.

In the following paragraphs, an example process of fabricating photonic elements is described, wherein the overgrown diamond thin film layer that the photonic element is fabricated into is then bonded, via a flip-chip bonding technique, to a semiconductor substrate. As indicated in FIG. 7A, this process continues from the processes described above with regard to FIG. 2A-6 and, as such, 3D stack 600 is considered to be a starting point in the figure. It should be understood, however, that according to a particular charge state of the intended color centers that are to result from a given version of workflow illustrated by FIG. 7A-7G, overgrown diamond thin film 606 may resemble a doped overgrown diamond thin film, such as doped diamond thin film 504, or an un-doped overgrown diamond thin film layer. As such, 3D stack 500 is also meant to be incorporated into the discussions herein regarding FIG. 7A-7G.

FIG. 7A illustrates an overgrown diamond thin film that has been grown on top of a diamond substrate, wherein a nano-aperture is prepared via a masking step, according to some embodiments.

As shown in FIG. 7A and via arrow 700, a layer of resist 706 is deposited on top of overgrown diamond thin film 606. The resist is patterned according to a mask and using electron beam lithography, such that a nano-aperture 704 is formed, exposing the corresponding portion of the underlying overgrown diamond thin film 606. The result is depicted by 3D stack 702.

One nano-aperture 704 is shown in FIG. 7A for ease of discussion herein. However, more than one nano-aperture may be applied at this stage, according to a number of total color centers that are to be fabricated into 3D stack 702.

As introduced above with regard to FIG. 6, the introduction of and specific location of nano-aperture 704 along the XY plane may be based, at least in part, on an alignment with respect to two or more alignment markers that have been previously etched into overgrown diamond thin film 606, such as alignment markers 602 and 604.

FIG. 7B illustrates a result of an ion implantation step, wherein ions have become embedded into both the resist and the overgrown diamond thin film, according to some embodiments.

Arrow 710 represents a high-energy ion implantation step, followed by a high-temperature annealing step. Ions 708, such as Si⁺ ions, may be implanted such that a portion of the ions are implanted into resist 706 and another portion of ion(s) is implanted into the overgrown diamond thin film 318 via nano-aperture 704. The result is depicted by 3D stack 712. As depicted in FIGS. 7B and 7C, ions that are implanted into resist 706 are removed once resist 706 is removed, and the intended ion that is implanted into overgrown diamond thin film 606 at the location of nano-aperture 704 becomes color center 720.

Arrow 710 illustrates embodiments in which a high-energy ion implantation step is used to implant ions 708. However, in other embodiments, a focused ion beam (FIB) implantation process may instead be applied, in which highly focused and collimated ions are implanted at a controlled and engineered location (e.g., at the location of nano-aperture 704). In such other embodiments, the location of the implantation of focused and collimated ions is still determined with respect to alignment markers 602 and 604.

FIG. 7C illustrates trenches that are etched into both the overgrown diamond thin film and damaged layers, in preparation for allowing access for etching fluid to reach the smart-cut layer, according to some embodiments.

Based on the post-annealing that is described above with regard to arrow 710, the ion that was implanted into overgrown diamond thin film 606 now forms a color center. In some embodiments in which ions 708 are Si⁺-type ions, then the color center is an SiV⁻ in diamond color center, such as that which was introduced in FIG. 1B, and is also further described with regard to SiV⁻ color center 802.

FIG. 7A-7G depict examples in which ions 708 are Si⁺ ions, and therefore the resulting color center is an SiV⁻ in diamond type of color center, wherein the SiV color center is negatively charged. In other embodiments, however, ions 708 may instead be nitrogen ions, germanium ions, tin ions, lead ions, etc., and the resulting color center thus changes accordingly. Moreover, and as introduced above with regard to doped diamond thin film 504, a charge state of the color center may also vary according to whether or not the overgrown diamond thin film 606 that is depicted in FIG. 7C has been doped according to processes described above with regard to FIG. 5.

Arrow 714 indicates another masking step, wherein trenches 718 and 722 are formed on either side of color center 720 along the XY plane. The result is depicted by 3D stack 716. As shown by 3D stack 716, trenches 718 and 722 extend from the top surface of 3D stack 716 down to the smart-cut layer 310 in the Z dimension.

FIG. 7D illustrates that the majority of the smart-cut layer has been selectively etched away, such that tethers between the damaged layer and diamond substrate remain, according to some embodiments.

Arrow 724 represents a selective undercutting process, such as that which may be enabled by electrochemical etching, wherein large portions of smart-cut layer 310 are removed. As shown in resulting 3D stack 726, tethers 728 and 730 are small portions of smart-cut layer 310 that remain after the electrochemical etching process is complete. Tethers 728 and 730 hold the damaged layer 312 and overgrown diamond thin film 606 in place, in preparation for the flip-chip bonding process that is to follow.

FIG. 7E illustrates an application of a bonding layer to the top surface of the overgrown diamond thin film, and also to a top surface of a separate semiconductor substrate, according to some embodiments.

Arrow 732 indicates a deposition step in which an adhesive or bonding layer is deposited. As shown in FIGS. 7E and 3D stack 734, bonding layer 736 is deposited onto the top surface of the overgrown diamond thin film 606. In some embodiments, bonding layer 736 may be made of silicon oxide, aluminum oxide, copper, aluminum, gold, or some other metal, oxide, semiconductor, or organic material.

Arrow 732 also refers to a deposition of bonding layer 736 onto a separate semiconductor substrate 738. Semiconductor substrate 738 may resemble semiconductor substrate 104, and may also have semiconductor circuit elements that are already patterned into a top surface of semiconductor substrate 738. As introduced via integrated semiconductor and photonic elements 106 in FIG. 1B, additional elements may be fabricated onto and into semiconductor substrate 738 in order to provide optical access to the optically active quantum memories that are fabricated into overgrown diamond thin film 606. In addition, various elements for electrical, optical, or mechanical tuning of the optically active quantum memories may also be fabricated onto and into semiconductor substrate 738.

Examples of elements that may be patterned onto or into semiconductor substrate 738 include coplanar waveguides, which are configured to deliver microwave signals to the optically active quantum memories, or grating couplers, which are configured to couple light from photonic structures in diamond to photonic structures in the underlying semiconductor substrates, etc.

Additional examples of how semiconductor substrate 738 is both optically and electronically functionalized prior to performing the flip-chip bonding process illustrated in FIG. 7F are also discussed with regard to portion 900 of wafer 100 in FIG. 9. Moreover, semiconductor substrate 738 is functionalized prior to it being bonded to overgrown diamond thin film 606 as much as is feasible in typical cleanroom environments such that an amount of further fabrication processing steps that occur after the flip-chip bonding process is kept to a minimum, as these further fabrication processing steps risk to inadvertently damage or degrade the quantum-grade qualities of overgrown diamond thin film 606.

As also illustrated in FIG. 7E, alignment markers 740 and 742 are patterned (e.g., either deposited or etched) onto a top surface of semiconductor substrate 738. The locations of alignment markers 740 and 742 along the top surface of semiconductor substrate 738 are specifically designed to align with alignment markers 602 and 604 during a passive alignment step of the flip-chip bonding process shown in FIG. 7F below. In some embodiments, alignment markers 740 and 742 may be deposited onto the top surface of semiconductor substrate 738. However, alignment markers 740 and 742 may, in other embodiments, be etched into the top surface of semiconductor substrate 738.

FIG. 7F illustrates a flip-chip bonding technique, wherein the overgrown diamond thin film is bonded to the semiconductor substrate via the bonding layer, and wherein the remaining diamond substrate is removed, according to some embodiments.

Arrow 744 represents a pressure and temperature based flip-chip bonding technique that bonds overgrown diamond thin film 606 to semiconductor substrate 738 via bonding layer 736, which acts as an intermediary layer. Moreover, and as shown via 3D stack 746, tethers 728 and 730, and diamond substrate 302 are removed, such that 3D stack 746 includes remaining portions of damage layer 312, overgrown diamond thin film layer 606 with color center 720, bonding layer 736, and semiconductor substrate 738.

As introduced above, alignment markers 602 and 604 that are etched into overgrown diamond thin film 606 are aligned to alignment markers 740 and 742 of semiconductor substrate 738. This ensures an alignment between overgrown diamond thin film layer 606 to semiconductor substrate 738 with micron-level accuracy. More specifically, arrow 744 includes an optical imaging or optical lithography based alignment step, in which alignment markers 602 and 604 and 740 and 742 are passively aligned. As opposed to an active alignment process, wherein some initial alignment is attempted, a measurement is performed, the alignment is adjusted based on the measurement, and so on during an iterative and cumbersome process that does not allow for scaling up to mass production within a foundry or industry cleanroom environment, arrow 744 refers specifically to a passive alignment of overgrown diamond thin film 606 and semiconductor substrate 738. Passive alignment, as used herein, refers to performing exactly one measurement, using optical imaging or optical lithography techniques, to locate alignment markers 602, 604, 740, and 742, or some combination therein. After location is confirmed by the exactly one measurement, the flip-chip bonding process described by arrow 744 may proceed.

FIG. 7G illustrates a removal of the damaged layer and further etching of the overgrown diamond thin film layer, wherein an amount that is etched away from the overgrown diamond thin film layer is determined based on to intended optical properties of the resulting optically active quantum memories, according to some embodiments.

Arrow 748 refers to an etching away of the damaged layer 312, in addition to some portion of overgrown diamond thin film 606. Firstly, damaged layer 312 is fully removed from the top surface of 3D stack 746 via an etching process step. Next, a uniform portion of overgrown diamond thin film 606 is also removed via an etching process step.

The removal of at least 500 nm of material from the damaged layer 312 and, in some embodiments, a remaining portion of the 500 nm that comes from overgrown diamond thin film 606, directly impacts and improves the optical linewidths of the resulting optically active quantum memories. Any additional thinning of overgrown diamond thin film 606 that is made during this etching process step (e.g., arrow 748), is then based on a need to conform to a target device thickness. For example, optical properties of the cavities that are formed proximate to the color centers (see also the thru-holes illustrated in FIGS. 8A and 8B herein) are tuned based, at least in part, on the thinning of overgrown diamond thin film 606.

In some embodiments, overgrown diamond thin film 606 and damaged layer 312 may have a thickness of approximately several microns in the Z dimension of 3D stack 746. After the etching process steps denoted by arrow 748 are complete, the remaining overgrown diamond thin film 606 may have a thickness of approximately 100-300 nm in the Z dimension of 3D stack 750. An exact thickness of overgrown diamond thin film 606 in 3D stack 750 depends upon the intended linewidths of the desired optically active quantum memories, on the intended target device thickness, and various other optical properties of the resulting devices that have been formed onto and into wafer 100, and thus the remaining thickness may be greater than 300 nm according to various other implementations.

FIGS. 8A and 8B illustrate cross-sectional and top-down view, respectively, of a quantum information storage device that is fabricated using a quantum-grade diamond thin film that has been bonded to a semiconductor substrate, according to some embodiments.

Quantum information storage device 800 depicts a future moment in time after which point 3D stack 750 has been used to generate the photonic structures seen in FIGS. 8A and 8B. Beginning from 3D stack 750, the thru-holes shown in FIGS. 8A and 8B may be fabricated using a silicon nitride hard mask and Electron-beam (E-beam) lithography, for example, or using optical lithography, etc. The overgrown diamond thin film layer 606 is then undercut using a combination of gold etchant, hydrofluoric acid, and Xenon difluoride etchant. The specific etch chemistries chosen to perform the undercut may vary with the choice of substrate or bonding layer. Moreover, in some embodiments, such as those in which silicon dioxide is used as the bonding layer, the undercut step may be skipped entirely. The result is semiconductor substrate 808 that is bonded to diamond thin film layer 804 via bonding layer 806. As such, SiV⁻color center 802 is equipped with thru-holes on either side of the color center that collectively function as mirrors to temporarily trap incoming light. A localization of the etching the thru-holes may be completed by referencing some combination of alignment markers 602, 604, 740, and 742.

FIG. 9 further illustrates example layouts of the integrated semiconductor and photonic elements introduced in the bulk wafer that is shown in FIGS. 1A and 1B, wherein the fabrication processes described herein enable those layouts, according to some embodiments.

The fabrication processes described herein may also be used to extend quantum information storage device 800 to that which is shown in portion 900 of wafer 100, which is configured to receive incoming photons via optical fiber 902 and route the photons to optically active quantum memories 904 via optical switch network 906. A given one of the optically active quantum memories 904 that has been fabricated into bonded diamond thin film 910 is then configured to interact with the incoming photons such that quantum information is transferred to the SiV⁻ cavity of the quantum memory module.

As shown in FIG. 9, various bonded diamond thin films 910 host quantum memory locations, which are then coupled to various other optical and/or electrical circuit components of wafer 900 that have been fabricated into semiconductor substrate 908. For example, electrical control signals may be routed through semiconductor substrate 908 to optically active quantum memories 904, wherein those microwave or RF frequency control signals may then be used to control a superposition state of a given qubit within a respective quantum memory module. In a second example, in some embodiments in which quantum memories of optically active quantum memories 904 are implemented as nanophotonic cavities, DC or low-frequency AC electric fields may be used to tune the color center resonances of such nanophotonic cavities. In a third example, such electrical control signals may also be configured to limit cross talk and excess heating of the quantum memories on wafer 900.

Referring to both portion 900 and to wafer 100 in FIGS. 1A, 1B, and 9, it is understood that hundreds if not thousands of optically active quantum memories may be fabricated using the methods described herein in parallel with one another and subsequently installed onto a same wafer 100 using flip-chip bonding. By fabricating components of these overall quantum information storage devices using the same fabrication tool recipes and within a same wafer batch, uniformity, consistency, and repeatability of such techniques is ensured. This guarantees the ability to mass-produce quantum information storage devices, thus also guaranteeing that there is limited to no variability that is specifically incurred due to the use of inefficient active alignment methods, for example, or due to variation in growth processes of the overgrown diamond thin films, etc. This firmly places the fabrication processes described herein, wherein components are passively, not actively, aligned and wherein the batch-growth of the diamond thin films, within the bounds of any small and expected amount of variation that is tolerated within foundry and industry cleanroom environments due to any mass-produced wafer fabrication process.

FIG. 10 is a block diagram illustrating an example computing device that may be used in at least some embodiments.

FIG. 10 illustrates such a general-purpose computing device 1000 as may be used in any of the embodiments described herein. In the illustrated embodiment, computing device 1000 includes one or more processors 1010 coupled to a system memory 1030 (which may comprise both non-volatile and volatile memory modules) via an input/output (I/O) interface 1020. Computing device 1000 further includes a network interface 1060 coupled to I/O interface 1020.

In various embodiments, computing device 1000 may be a uniprocessor system including one processor 1010, or a multiprocessor system including several processors 1010 (e.g., two, four, eight, or another suitable number). Processors 1010 may be any suitable processors capable of executing instructions. For example, in various embodiments, processors 1010 may be general-purpose or embedded processors implementing any of a variety of instruction set architectures (ISAs), such as the x86, PowerPC, SPARC, or MIPS ISAs, or any other suitable ISA. In multiprocessor systems, each of processors 1010 may commonly, but not necessarily, implement the same ISA. In some implementations, graphics processing units (GPUs) may be used instead of, or in addition to, conventional processors.

System memory 1030 may be configured to store instructions and data accessible by processor(s) 1010. In at least some embodiments, the system memory 1030 may comprise both volatile and non-volatile portions; in other embodiments, only volatile memory may be used. In various embodiments, the volatile portion of system memory 1030 may be implemented using any suitable memory technology, such as static random-access memory (SRAM), synchronous dynamic RAM or any other type of memory. For the non-volatile portion of system memory (which may comprise one or more NVDIMMs, for example), in some embodiments flash-based memory devices, including NAND-flash devices, may be used. In at least some embodiments, the non-volatile portion of the system memory may include a power source, such as a supercapacitor or other power storage device (e.g., a battery). In various embodiments, memristor based resistive random-access memory (ReRAM), three-dimensional NAND technologies, Ferroelectric RAM, magnetoresistive RAM (MRAM), or any of various types of phase change memory (PCM) may be used at least for the non-volatile portion of system memory. In the illustrated embodiment, program instructions and data implementing one or more desired functions, such as those methods, techniques, and data described above, are shown stored within system memory 1030 as code 1040 and data 1050.

In some embodiments, I/O interface 1020 may be configured to coordinate I/O traffic between processor 1010, system memory 1030, and any peripheral devices in the device, including network interface 1060 or other peripheral interfaces such as various types of persistent and/or volatile storage devices. In some embodiments, I/O interface 1020 may perform any necessary protocol, timing or other data transformations to convert data signals from one component (e.g., system memory 1030) into a format suitable for use by another component (e.g., processor 1010). In some embodiments, I/O interface 1020 may include support for devices attached through various types of peripheral buses, such as a variant of the Peripheral Component Interconnect (PCI) bus standard or the Universal Serial Bus (USB) standard, for example. In some embodiments, the function of I/O interface 1020 may be split into two or more separate components, such as a north bridge and a south bridge, for example. Also, in some embodiments some or all of the functionality of I/O interface 1020, such as an interface to system memory 1030, may be incorporated directly into processor 1010.

Network interface 1060 may be configured to allow data to be exchanged between computing device 1000 and other devices 1080 attached to a network or networks 1070, such as other computer systems or devices as illustrated in FIG. 1A through FIG. 9, for example. In various embodiments, network interface 1060 may support communication via any suitable wired or wireless general data networks, such as types of Ethernet network, for example. Additionally, network interface 1060 may support communication via telecommunications/telephony networks such as analog voice networks or digital fiber communications networks, via storage area networks such as Fibre Channel SANs, or via any other suitable type of network and/or protocol.

In some embodiments, system memory 1030 may represent one embodiment of a computer-accessible medium configured to store at least a subset of program instructions and data used for implementing the methods and apparatus discussed in the context of FIG. 1A through FIG. 9. However, in other embodiments, program instructions and/or data may be received, sent or stored upon different types of computer-accessible media. Generally speaking, a computer-accessible medium may include non-transitory storage media or memory media such as magnetic or optical media, e.g., disk or DVD/CD coupled to computing device 1000 via I/O interface 1020. A non-transitory computer-accessible storage medium may also include any volatile or non-volatile media such as RAM (e.g., SDRAM, DDR SDRAM, RDRAM, SRAM, etc.), ROM, etc., that may be included in some embodiments of computing device 1000 as system memory 1030 or another type of memory. In some embodiments, a plurality of non-transitory computer-readable storage media may collectively store program instructions that when executed on or across one or more processors implement at least a subset of the methods and techniques described above. A computer-accessible medium may further include transmission media or signals such as electrical, electromagnetic, or digital signals, conveyed via a communication medium such as a network and/or a wireless link, such as may be implemented via network interface 1060. Portions or all of multiple computing devices such as that illustrated in FIG. 10 may be used to implement the described functionality in various embodiments; for example, software components running on a variety of different devices may collaborate to provide the functionality. In some embodiments, portions of the described functionality may be implemented using storage devices, network devices, or special-purpose computer systems, in addition to or instead of being implemented using general-purpose computer systems. The term “computing device”, as used herein, refers to at least all these types of devices, and is not limited to these types of devices.

Various embodiments may further include receiving, sending or storing instructions and/or data implemented in accordance with the foregoing description upon a computer-accessible medium. Generally speaking, a computer-accessible medium may include storage media or memory media such as magnetic or optical media, e.g., disk or DVD/CD-ROM, volatile or non-volatile media such as RAM (e.g., SDRAM, DDR, RDRAM, SRAM, etc.), ROM, etc., as well as transmission media or signals such as electrical, electromagnetic, or digital signals, conveyed via a communication medium such as network and/or a wireless link.

The various methods as illustrated in the Figures and described herein represent exemplary embodiments of methods. The methods may be implemented in software, hardware, or a combination thereof. The order of method may be changed, and various elements may be added, reordered, combined, omitted, modified, etc.

Various modifications and changes may be made as would be obvious to a person skilled in the art having the benefit of this disclosure. It is intended to embrace all such modifications and changes and, accordingly, the above description to be regarded in an illustrative rather than a restrictive sense.

What is claimed is:

1. A method for fabricating optically active quantum memories, the method comprising:
depositing overgrown diamond thin film layers onto top surfaces of corresponding diamond substrates;
etching alignment markers into top surfaces of the overgrown diamond thin film layers;
implanting silicon ions into the top surfaces of the overgrown diamond thin film layers, wherein the implanting is localized by referencing the alignment markers;
performing flip-chip bonding, wherein the performing the flip-chip bonding comprises bonding, using a deposited bonding layer as an intermediary layer, the top surfaces of the overgrown diamond thin film layers and a top surface of a separate semiconductor substrate to one another;
removing the diamond substrates; and
etching thru-holes into the top surfaces of the overgrown diamond thin film layers and proximate to the implanted silicon ions, wherein:
the etching is localized by referencing the alignment markers; and
the implanted silicon ions and the thru-holes form the optically active quantum memories.

2. The method of claim 1, wherein:
the method further comprises patterning additional alignment markers onto the top surface of the separate semiconductor substrate; and
the performing the flip-chip bonding further comprises aligning the alignment markers on the top surfaces of the overgrown diamond thin film layers to the additional alignment markers on the top surface of the separate semiconductor substrate.

3. The method of claim 2, wherein the aligning the alignment markers on the top surfaces of the overgrown diamond thin film layers to the additional alignment markers on the top surface of the separate semiconductor substrate is a passive alignment that is completed using an optical-based alignment.

4. The method of claim 1, further comprising:
determining a concentration of additional ions to implant into the overgrown diamond thin film layers in order to tune an optical or electrical property of the optically active quantum memories; and
implanting the additional ions, at the determined concentration, into the overgrown diamond thin film layers.

5. The method of claim 1, further comprising:
determining a concentration of gas to emit during the depositing the overgrown diamond thin film layers in order to tune an optical or electrical property of the optically active quantum memories; and
emitting the concentration of the gas during the depositing the overgrown diamond thin film layers.

6. The method of claim 1, wherein the implanting the silicon ions into the top surfaces of the overgrown diamond thin film layers comprises:
depositing a resist layer onto the top surfaces of the overgrown diamond thin film layers;
etching nano-apertures into the resist layer, based on referencing the alignment markers, such that portions of the top surfaces of the overgrown diamond thin film layers are exposed while other portions of the top surfaces of the overgrown diamond thin film layers remain covered by the resist layer;
uniformly implanting the silicon ions; and
removing the resist layer.

7. The method of claim 1, wherein the implanting the silicon ions onto the top surfaces of the overgrown diamond thin film layers comprises:
determining intended locations of silicon vacancies based on referencing the alignment markers; and
implanting the silicon ions using a focused ion beam implantation.

8. The method of claim 1, further comprising:
prior to the depositing the overgrown diamond thin film layers,
determining, based on intended optical properties of the optically active quantum memories, a given miscut angle to cut the top surfaces of the corresponding diamond substrates along; and
cutting the top surfaces of the corresponding diamond substrates along the given miscut angle.

9. The method of claim 1, wherein the depositing the overgrown diamond thin film layers is performed using chemical vapor deposition.

10. The method of claim 9, further comprising:
determining temperature and electrical field conditions that are to be used during the depositing, via chemical vapor deposition, the overgrown diamond thin film layers based on intended optical properties of the optically active quantum memories; and
applying the determined temperature and electrical field conditions during the depositing.

11. The method of claim 1, further comprising:
prior to the etching the thru-holes, uniformly etching a portion of the overgrown diamond thin film layers, wherein the etched portion is determined based on intended optical properties of the optically active quantum memories.

12. The method of claim 1, wherein a localization of the etching the thru-holes comprises use of Electron-beam lithography and a reference to additional alignment markers that have been patterned onto the top surface of the separate semiconductor substrate.

13. The method of claim 1, wherein the separate semiconductor substrate is made from one or more of the following:
silicon;
silicon nitride;
silicon oxide;
lithium niobate;
aluminum nitride;
aluminum oxide; or
gallium arsenide.

14. The method of claim 1, wherein the deposited bonding layer is made from one of the following:
silicon oxide;
aluminum oxide;
copper;
aluminum; or
gold.

15. A method for fabricating quantum devices, the method comprising:
receiving a set of three-dimensional stacks, comprising overgrown diamond thin film layers that have been grown onto top surfaces of corresponding diamond substrates;
etching alignment markers into top surfaces of the overgrown diamond thin film layers;
implanting ions into the top surfaces of the overgrown diamond thin film layers, wherein the implanting is localized by referencing the alignment markers;
receiving a semiconductor substrate;
patterning additional alignment markers onto a top surface of the semiconductor substrate;
performing flip-chip bonding, wherein the performing the flip-chip bonding comprises:
aligning the alignment markers on the top surfaces of the overgrown diamond thin film layers to the additional alignment markers on the top surface of the semiconductor substrate; and
bonding, using a deposited bonding layer as an intermediary layer, the top surfaces of the overgrown diamond thin film layers and a top surface of a separate semiconductor substrate to one another;
removing the diamond substrates; and
etching thru-holes into the top surfaces of the overgrown diamond thin film layers and proximate to the implanted ions, wherein:
the etching is localized by referencing some combination of the alignment markers and the additional alignment markers; and
the implanted ions and the thru-holes form the quantum devices.

16. The method of claim 15, wherein the deposited bonding layer is made from one of the following:
silicon oxide;
aluminum oxide;
copper;
aluminum; or
gold.

17. The method of claim 15, further comprising:
prior to the etching the thru-holes, uniformly etching a portion of the top surfaces of the overgrown diamond thin film layers, wherein the etched portion is determined based on intended optical properties of the quantum devices.

18. The method of claim 15, wherein a localization of the etching the thru-holes comprises use of Electron-beam lithography or optical lithography and a reference to additional alignment markers that have been patterned onto the top surface of the separate semiconductor substrate.

19. A method for fabricating optically active quantum memories, the method comprising:
depositing, via chemical vapor deposition, overgrown diamond thin film layers onto top surfaces of corresponding diamond substrates, wherein gaps between respective ones of the overgrown diamond thin film layers within a chemical vapor deposition chamber are determined to ensure uniformity of deposition of the overgrown diamond thin film layers with respect to one another;
implanting silicon ions into portions of the top surfaces of the overgrown diamond thin film layers;
performing flip-chip bonding, wherein the performing the flip-chip bonding comprises bonding, using a deposited bonding layer as an intermediary layer, the top surfaces of the overgrown diamond thin film layers and a top surface of a separate semiconductor substrate to one another;
removing the diamond substrates; and
etching thru-holes into the top surfaces of the overgrown diamond thin film layers and proximate to the implanted silicon ions, wherein the implanted silicon ions and the thru-holes form the optically active quantum memories.

20. The method of claim 19, further comprising:
determining temperature and electrical field conditions that are to be used during the depositing, via the chemical vapor deposition, the overgrown diamond thin film layers based on intended optical properties of the optically active quantum memories; and
applying the determined temperature and electrical field conditions during the depositing.
